(19) United States
(12) Patent Application Publication
(10) Pub. No.: US 2016/0071994 A1
(43) Pub. Date: Mar. 10, 2016

(54) METHOD OF MAKING PHOTOVOLTAIC DEVICES WITH REDUCED CONDUCTION BAND OFFSET BETWEEN PNICTIDE ABSORBER FILMS AND EMITTER FILMS

(71) Applicants: DOW GLOBAL TECHNOLOGIES LLC, Midland, MI (US); CALIFORNIA INSTITUTE OF TECHNOLOGY, Pasedena, CA (US)

(72) Inventors: Jeffrey P. Bosco, Pasadena, CA (US); Gregory M. Kimball, Campbell, CA (US); Harry A. Atwater, South Pasadena, CA (US); Nathan S. Lewis, La Canada, CA (US); Rebekah K. Feist, Midland, MI (US); Marty W. DeGroot, Middletown, DE (US)

(21) Appl. No.: 14/373,599

(22) PCT Filed: Jan. 30, 2013
(86) PCT No.: PCT/US2013/023819

§ 371 Date: Jul. 21, 2014

Related U.S. Application Data
(60) Provisional application No. 61/592,957, filed on Jan. 31, 2012.

(51) Int. Cl. H01L 31/072; H01L 31/18

(52) U.S. Cl. CPC H01L 31/072; H01L 31/18

(57) ABSTRACT

The principles of the present invention are used to reduce the conduction band offset between chalcogenide emitter and pnictide absorber films. Alternatively stated, the present invention provides strategies to more closely match the electron affinity characteristics between the absorber and emitter components. The resultant photovoltaic devices have the potential to have higher efficiency and higher open circuit voltage. The resistance of the resultant junctions would be lower with reduced current leakage. In illustrative modes of practice, the present invention incorporates one or more tuning agents into the emitter layer in order to adjust the electron affinity characteristics, thereby reducing the conduction band offset between the emitter and the absorber. In the case of an n-type emitter such as ZnS or a tertiary compound such as zinc sulfide selenide (optionally doped with Al) or the like, an exemplary tuning agent is Mg when the absorber is a p-type pnictide material such as zinc phosphide or an alloy of zinc phosphide incorporating at least one additional metal in addition to Zn and optionally at least one non-metal in addition to phosphorus. Consequently, photovolotaic devices incorporating such films would demonstrate improved electronic performance.

### PRIORITY

This application claims priority under 35 U.S.C. §119(e) to U.S. provisional application No. 61/592,957, titled “METHOD OF MAKING PHOTOVOLTAIC DEVICES WITH REDUCED CONDUCTION BAND OFFSET BETWEEN PNICTIDE ABSORBER FILMS AND EMITTER FILMS”, filed Jan. 31, 2012, wherein the entirety of this application is incorporated herein by reference in its entirety for all purposes.

### FIELD OF THE INVENTION

The present invention relates to methods of forming solid state junctions incorporating p-type, pnictide semiconductor absorber compositions and n-type Group II/Group VI compositions. More specifically, the present invention relates to methods of improving the quality of these heterojunctions by incorporating agent(s) into the emitter that reduce the conduction band offset between the absorber and the emitter.

### BACKGROUND OF THE INVENTION

Pnictide-based semiconductors include the Group IIB/VA semiconductors. Zinc phosphide (Zn₃P₂) is one kind of Group IIB/VA semiconductor. Zinc phosphide and similar pnictide-based semiconductor materials have significant potential as photoactive absorbers in thin film photovoltaic devices. Zinc phosphide, for example, has a reported direct band gap of 1.5 eV, high light absorbance in the visible region (e.g., greater than 10⁴ to 10⁵ cm⁻¹), and long minority carrier diffusion lengths (about 5 to about 10 μm). This would permit high current collection efficiency. Also, materials such as Zn and P are abundant and low cost.

Pnictide-based semiconductors include the Group IIB/VA semiconductors. Zinc phosphide (Zn₃P₂) is one kind of Group IIB/VA semiconductor. Zinc phosphide and similar pnictide-based semiconductor materials have significant potential as photoactive absorbers in thin film photovoltaic devices. Zinc phosphide, for example, has a reported direct band gap of 1.5 eV, high light absorbance in the visible region (e.g., greater than 10⁴ to 10⁵ cm⁻¹), and long minority carrier diffusion lengths (about 5 to about 10 μm). This would permit high current collection efficiency. Also, materials such as Zn and P are abundant and low cost.

Zinc phosphide is known to be either p-type or n-type. To date, it has been much easier to fabricate p-type zinc phosphide. Preparing n-type zinc phosphide, particularly using methodologies suitable for the industrial scale, remains challenging. This has confounded the fabrication of p-n homojunctions based upon zinc phosphide. Consequently, solar cells using zinc phosphide most commonly are constructed with Mg Schottky contacts or p/n heterojunctions. Exemplary photovoltaic devices include those incorporating Schottky contacts based upon p-Zn₃P₂/Mg and have exhibited about 5.9% efficiency for solar energy conversion. The efficiency of such diodes theoretically limits open circuit voltage to about 0.5 volts due to the about 0.8 eV barrier height obtained for junctions comprising Zn₃P₂ and metals such as Mg.

Much research and development effort is focused upon improving the electronic performance of optoelectronic devices, particularly photovoltaic devices that incorporate pnictide-based semiconductors. One challenge involves forming high quality, solid state photovoltaic junctions that incorporate p-type pnictide semiconductors as absorber layers and n-type, Group II/Group VI semiconductors as emitter layers. Chalcogenides of zinc, such as ZnS and ZnSe, are exemplary Group II/GroupVI semiconductors. ZnS offers many advantages when suggested as a component for use in a photovoltaic heterojunction with a p-type pnictide semiconductor such as p-type zinc phosphide. ZnS offers good lattice match characteristics, electronic compatibility, complementary fabrication, and low electronic defects at the heterojunction interface. However, the conduction band offset between an emitter such as ZnS and a pnictide absorber film such as Zn₃P₂ can be greater than desired. This represents a direct loss in V_{oc} (open circuit voltage) due to a decrease in the fundamental barrier height of the heterojunction, or an undue increase in electrical resistance associated with the impedance of charged carrier transport across the junction. Ideally, a conduction band offset as close to zero as possible is preferred in order to achieve the best photovoltaic device performance. In the ease of an n-type ZnS/p-type Zn₃P₂ heterojunction, a theoretical conduction band offset of 300 mV is expected, thereby decreasing the expected V_{oc} of a device by a corresponding quantity.

Thus, notwithstanding the potential advantages of using n-type materials such as ZnS in combination with p-type materials such as Zn₃P₂ in photovoltaic junctions, the materials have remained too dissimilar to achieve higher levels of performance. Strategies for making solid-state, photovoltaic junctions that more effectively integrate p-type pnictide materials with compatible, well-matched n-type materials are desired.

### SUMMARY OF THE INVENTION

The principles of the present invention are used to improve the quality photovoltaic junctions that incorporate components including pnictide absorber films and emitter films, e.g., a solid state p-n heterojunction, a solid state p-i-n heterojunction, or the like. As an overview, the principles of the present invention are used to reduce the conduction band offset between the emitter and absorber films. Alternatively stated, the present invention provides strategies to more closely match the electron affinity characteristics between the absorber and emitter components. The resultant photovoltaic devices have the potential to have higher efficiency and higher open circuit voltage. In illustrative modes of practice, the present invention incorporates one or more tuning agents into the emitter layer in order to adjust the electron affinity characteristics, thereby reducing the conduction band offset between the emitter and the absorber. In the case of an n-type emitter such as ZnS or a ternary compound such as zinc sulfide selenide (optionally doped with Al) or the like, an exemplary tuning agent is Mg. Mg is particularly suitable as a tuning agent for an n-type emitter when the absorber is a p-type pnictide material such as zinc phosphide or an alloy of zinc phosphide incorporating at least one additional metal in addition to Zn and optionally at least one non-metal in addition to phosphorus. Consequently, photovoltaic devices incorporating such films would demonstrate improved electronic performance.

In some modes of practice, adding a tuning agent to reduce the conduction band offset may increase the degree of lattice mismatch between the absorber and the emitter films. Accordingly, the present invention also offers strategies to enhance lattice matching, making the conduction band tuning strategies even more effective.

In one aspect, the present invention relates to a method of making a solid state photovoltaic heterojunction or precursor thereof, comprising the steps of:
a. providing a p-type pnictide semiconductor film; and
b. forming a chalcogenide semiconductor film directly or indirectly on the pnictide semiconductor film, said semiconductor chalcogenide film comprising at least one Group II element and at least one Group VI element, and wherein at least a portion of the chalcogenide semiconductor film proximal to the pnictide semiconductor film incorporates at least one tuning agent (preferably a metal that is alloyable with the composition, such as Mg and/or Ca, but other examples include Sn, F, and/or Cd) that reduces the conduction band offset between the pnictide semiconductor film and the chalcogenide semiconductor film relative to an otherwise identical chalcogenide semiconductor film composition formed under the same conditions with none or lesser amount(s) of the at least one tuning agent.

In another aspect, the present invention relates to a method of making a solid state photovoltaic heterojunction or precursor thereof, comprising the steps of:
a. providing a p-type pnictide semiconductor film; and
b. forming an-n-type semiconductor film directly or indirectly on the p-type pnictide semiconductor film, said forming comprising the steps of:
   i. heating a compound comprising at least one Group II element and at least one Group VI element to generate a vapor species;
   ii. depositing the vapor species or a derivative thereof directly or indirectly onto the p-type pnictide semiconductor film; and
   iii. co-depositing at least one of Mg and Ca during at least a portion of the time that the n-type semiconductor film is deposited under conditions such that at least a portion of the formed n-type semiconductor film proximal to the p-type pnictide semiconductor film incorporates at least one of Mg and/or Ca.

In another aspect, the present invention relates to a photovoltaic device, comprising:
(a) a p-type absorber region comprising at least one p-type, pnictide semiconductor composition; and
(b) an n-type emitter region provided directly or indirectly on the absorber region, said emitter region comprising at least one Group II element and at least one Group VI element, and wherein at least a portion of the n-type emitter region proximal to the p-type absorber region incorporates at least one of Mg and/or Ca.

### BRIEF DESCRIPTION OF THE DRAWINGS

FIG. 1 is a schematic illustration of a photovoltaic device incorporating a heterojunction of the present invention.

### DETAILED DESCRIPTION OF PRESENTLY PREFERRED EMBODIMENTS

The embodiments of the present invention described below are not intended to be exhaustive or to limit the invention to the precise forms disclosed in the following detailed description. Rather the embodiments are chosen and described so that others skilled in the art may appreciate and understand the principles and practices of the present invention. All patents, pending patent applications, published patent applications, and technical articles cited herein are incorporated herein by reference in their respective entireties for all purposes.

For purposes of illustration, the principles of the present invention will be described in the context in which an n-type Group II/Group VI semiconductor tuned in accordance with principles of the present invention is used to form an emitter layer over a p-type, pnictide semiconductor film used as an absorber layer. The emitter layer and the absorber layer are integrated in a manner effective to form a photovoltaic junction such as a p-n photovoltaic junction in some embodiments or a p-i-n junction in other embodiments. Tuning of the emitter is used in this illustrative mode of practice to reduce the conduction band offset between the emitter and absorber layers. This kind of tuning offers the potential to increase the efficiency and the open circuit voltage of the resultant photovoltaic device.

In the practice of the present invention, conduction band offset is conceptually and qualitatively understood with respect to Anderson's model. This model also is referred to as the electron affinity rule. The model is discussed in S. M. Sze, Kwok Kwok Ng, Physics of semiconductor devices, John Wiley and Sons, (2007); Anderson, R. L., (1960). Germanium-gallium arsenide heterojunction, IBM J. Res. Dev. 4(3), pp. 283-287; Borisenko, V. E. and Ossicini, S. (2004). What is What in the Nanoworld: A Handbook on Nanoscience and Nanotechnology. Germany: Wiley-VCH; and Davies, J. H., (1997). The Physics of Low-Dimensional Semiconductors. UK: Cambridge University Press. Quantitative assessment of an actual conduction band offset between an absorber film and an emitter film is determined in accordance with the experimental procedure described below.

Anderson's model states that when constructing an energy band diagram, the vacuum levels of the two semiconductors on either side of the heterojunction should be aligned at the same energy. (Borisenko and Ossicini, 2004). Once the vacuum levels are aligned it is possible to use the electron affinity and band gap values for each semiconductor to calculate the conduction band and valence band offsets (Davies, 1997). The electron affinity (usually given the symbol x in solid state physics) gives the energy difference between the lower edge of the conduction band and the vacuum level of the semiconductor. The band gap (usually given the symbol E_{g}) gives the energy difference between the lower edge of the conduction band and the upper edge of the valence band. Each semiconductor has different electron affinity and band gap values. For semiconductor alloys it is desirable to use Vegard's law to calculate these values. Once the relative positions of the conduction and valence bands for both semiconductors are known, Anderson's model allows the calculation of conduction band offset (ΔE_{c}). Consider a heterojunction between semiconductor A and semiconductor B. Suppose the conduction band of semiconductor A lies at a higher energy than that of semiconductor B. The theoretical conduction band offset would then be given by:

ΔE_{c}χ_{B}−χ_{A}

In metallurgy, Vegard's law is an approximate empirical rule which holds that a linear relation exists, at constant temperature, between the crystal lattice parameter of an alloy and the concentrations of the constituent elements. See L. Vegard. Die Konstitution der Mischkristalle and die Raumfüllung der Atome. Zeitschrift für Physik, 5:17, 1921; Harvard.edu A. R. Denton and N. W. Ashcroft. Vegard's law. Phys. Rev. A, 43:3161-3164, March 1991.

For example, consider a semiconductor alloy of zinc, sulfur, and phosphorus, such as Zn₂₊ₓS₂₋₂ₓP₂ₓ or a semiconductor alloy of zinc, phosphorus and sulfur such as MgₓZn₁₋ₓS. A relation exists between the constituent elements and their associated lattice parameters, a, such that:

a_{Mg(x)Zn(1-x)S}=xa_{Mgs}+(1−x)a_{ZnS}

a_{Mg(3x)Zn3(1-x)P2}=xa_{Mg3P2}+(1−x)a_{Zn3P2}

One can also extend this relation to determine semiconductor band gap energies. The following is an expression that relates the band gap energies, E_{g}, to the ratio of the constituents and a bowing parameter b for each of the illustrative alloys:

Eg,_{Mg(x)Zn(1-x)S}=xEg,_{Mgs}+(1−x)Eg,_{ZnS}−bx(1−x)

Eg,_{Mg(3x)Zn3(1-x)P2}=xEg,_{Mg3P2}+(1−x)Eg,_{Zn3P2}−bx(1−x)

When variations in lattice parameter are very small across the entire composition range, Vegard's law becomes equivalent to Amagat's law. See J. H. Noggle, Physical Chemistry, 3rd Ed., Harper Collins, New York, 1996.

The previous discussion provides conduction band offset from a theoretical perspective. An actual conduction band offset between the two semiconductor materials can be determined via measurement from experimentation. According to modes of practicing the present invention, a method for experimentally determining the conduction band offset involves the use of X-ray photoelectron spectroscopy (XPS) to directly probe the valence band offset at the heterojunction interface. From the valence band offset and known values of the band gaps for each of the semiconductor materials comprising the heterojunction, the conduction band offset can be calculated by the following methodology.

High resolution XPS measurements of the core level positions and valence band maxima are collected for phase pure specimens of a single semiconductor. Typically, a vacuum deposited thin film in excess of 10 nm is used in order to avoid surface contamination. From this measurement, the core level (CL) to valence band maximum (VBM) energy difference (E_{CL}^{A}−E_{VBM}^{A}) is determined to a high precision for a single semiconductor (A). This procedure is repeated for both of the semiconductors comprising the heterojunction of interest. Next, an ultra-thin film of roughly 5 to 30 angstroms (0.5 to 3 nm) thickness of one semiconductor is deposited onto a bulk film (>10 nm) of the second semiconductor in order to create a thin heterojunction. The thickness of the ultrathin film is on the order of the escape depth of the photoelectrons created in order to actually probe the heterojunction. Typically several different film thicknesses are used (e.g, 10, 20, and 30 angstroms) for more precise measurements and the average of the values obtained for the various film thicknesses is used. The heterojunction is again probed using high resolution XPS with focus on the precise energy difference between the core levels of the two semiconductor (ΔE_{CL}^{B-A}). The valence band offset (ΔEᵥ) can then be calculated from the gathered XPS data as follows:

ΔE_{V}=(E_{CL}^{B}−E_{VBM}^{B})−(E_{CL}^{A}−E_{VBM}^{A})−(ΔE_{CL}^{B-A})

Finally, the conduction band offset can be calculated from the known band gaps of the two semiconductors comprising the heterojunction (E_{g,A} and E_{g,B}) and the measured valence band offset as follows:

ΔE_{C}=E_{g,B}−E_{g,A}−ΔE_{V}

The methodology described above can be applied to determine the valence and conduction band offsets for a Zn₃P₂/ZnS heterojunction. In this case, the energy difference between the Zn₃P₂ P 2p_{3/2,1/2} core level peak (binding energy of roughly 128 eV) and the Zn₃P₂ valence band maximum is measured on a pure Zn₃P₂ film, resulting in a value for the quantity (E_{CL}^{Zn3P2}−E_{VBM}^{Zn3P2}). Repeated high resolution XPS scans (at least about ten scans) from 160 to 0 eV binding energy are required to precisely determine this quantity. Using multiple scans improves the S/N ratio. The resultant summed peak values is used to compute the peak difference. The P 2p_{3/2,1/2} doublet is accurately fit using two pure Lorentzian functions, with the core level energy taken as the average of the two fitted peak energies. In a similar fashion, the energy difference between the ZnS S 2p_{3/2,1/2} core level peak (roughly 163 eV) and the ZnS valence band maximum is also determined for a pure ZnS film, providing a quantity for (E_{CL}^{ZnS}−E_{VBM}^{ZnS}). Next, a series of ultrathin (e.g., 5 angstroms to 30 angstroms) ZnS films are deposited on thicker Zn₃P₂ films. High resolution XPS scans over the binding energy region between 165 to 125 eV are recorded for the ultrathin heterojunction sample, capturing both the Zn₃P₂ P 2p_{3/2,1/2} and ZnS S 2p_{3/2,1/2} core levels, assuming the ZnS overlayer is not too thick. Using the same fitting procedure described above, the energy difference between the core levels is accurately determined, resulting in a quantity for (ΔE_{CL}^{ZnS-Zn3P2}). Finally, the valence band and conduction band offsets for the Zn₃P₂/ZnS heterojunction can be calculated using the revised equations below:

ΔE_{V}=(E_{CL}^{ZnS}−E_{VBM}^{ZnS})−(E_{CL}^{Zn3P2}−E_{VBM}^{Zn3P2})−(ΔE_{CL}^{ZnS-Zn3P2})

ΔE_{C}=E_{g,ZnS}−E_{g,Zn3P2}−ΔE_{V}

In actual practice, the theoretical and experimental conduction band offsets obtained with respect to an interface between two semiconductor materials may differ. In the practice of the present invention, the theoretical model and value are used to help qualitatively understand the concept of the conduction band offset, but the experimentally determined conduction band offset is controlling.

Tuning strategies of the present invention are used so that the experimentally obtained conduction band offset is as close to zero as is possible. By way of example, the magnitude of the conduction band offset preferably is less than 0.1 eV. In actual practice, it may be difficult to measure the conduction band offset to a precision better than, for instance, +/−0.07 eV. As experimental and instrumentation advances are made so that better precision is within the skill in the industry, the present invention contemplates that conduction band offset measurements even closer to zero than +/−0.07 eV would be practiced within the scope of the present invention. Most preferably, the conduction band offset is substantially 0 eV.

According to the method of the present invention, a pnictide semiconductor film or precursor thereof is provided on which the treatment method will be carried out. The term “pnictide” or “pnictide compound” refers to a molecule that includes at least one pnictogen and at least one element other than a pnictogen. The term “pnictogen” refers to any element from Group VA of the periodic table of elements. These also are referred to as Group VA or Group 15 elements. Pnictogens include nitrogen, phosphorus, arsenic, antimony, and bismuth. Phosphorus and arsenic are preferred. Phosphorus is most preferred.

In addition to the pnictogen(s), the other element(s) of a pnictide may be one or more metals, and/or nonmetals. In some embodiments, nonmetals may include one or more semiconductors. Examples of suitable metals and/or semiconductors include Si, the transition metals, Group IIB metals (Zn, Cd, Hg), metals included in the lanthanoid series, Al, Ga, In, Ti, Sn, Pb, combinations of these, and the like. In addition to the semiconductor materials noted above, other examples of such nonmetals include B, F, S, Se, Te, C, O, H, combinations of these, and the like. Examples of nonmetal pnictides include boron phosphide, boron nitride, boron arsenide, boron antimonide, combinations of these and the like. Pnictides that include both metal and nonmetal constituents in addition to one or more pnictogens are referred to herein as mixed pnictides. Examples of mixed pnictides include (a) at least one of Zn and/or Cd, (b) at least one of P, As, and/or Sb, and (c) at least one of Se and/or S, combinations of these, and the like.

Many embodiments of metal, non-metal, and mixed pnictides are photovoltaically active and/or display semiconductor characteristics. Examples of such photovoltaically active and/or semiconducting pnictides include phosphide, nitrides, antimonides, and/or arsenides of one or more of aluminum, boron, cadmium, gallium, indium, magnesium, germanium, tin, silicon, and/or zinc. Illustrative examples of such compounds include zinc phosphide, zinc antimonide, zinc arsenide, aluminum antimonide, aluminum arsenide, aluminum phosphide, boron antimonide, boron arsenide, boron phosphide, gallium antimonide, gallium arsenide, gallium phosphide, indium antimonide, indium arsenide, indium phosphide, aluminum gallium antimonide, aluminum gallium arsenide, aluminum gallium phosphide, aluminum indium antimonide, aluminum indium arsenide, aluminum indium phosphide, indium gallium antimonide, indium gallium arsenide, indium gallium phosphide, magnesium antimonide, magnesium arsenide, magnesium phosphide, cadmium antimonide, cadmium arsenide, cadmium phosphide, combinations of these and the like. Specific examples of these include Zn₃P₂; ZnP₂; ZnAr₂; ZnSb₂; ZnP₄; ZnP; combinations of these and the like.

Preferred embodiments of pnictide compositions comprise at least one Group IIB/VA semiconductor. A Group IIB/VA semiconductor generally includes (a) at least one Group IIB element and (b) at least one Group VA element. Examples of IIB elements include Zn and/or Cd. Zn is presently preferred. Examples of Group VA elements (also referred to as pnictogens) include one or more pnictogens. Phosphorous is presently preferred.

Exemplary embodiments of Group IIB/VA semiconductors include zinc phosphide (Zn₃P₂), zinc arsenide (Zn₃As₂), zinc antimonide (Zn₃Sb₂), cadmium phosphide (Cd₃P₂), cadmium arsenide (Cd₃As₂), cadmium antimonide (Cd₃Sb₂), combinations of these, and the like. Group IIB/VA semiconductors including a combination of Group IIB species and/or a combination of Group VA species (e.g., CdₓZn_{y}P₂, wherein each x and y is independently about 0.001 to about 2.999 and x+y is 3) also may be used. In an illustrative embodiment, the Group IIB/VA semiconductor material comprises p-type and/or n-type Zn₃P₂. Optionally, other kinds of semiconductor materials and dopants also may be incorporated into the composition.

All or a portion of the pnictide semiconductor film may be an alloy composition. A pnictide alloy is an alloy comprising at least two metal elements and further including one or more pnictogens. An alloy refers to a composition that is a mixture or solid solution composed of two or more elements. Complete solid solution alloys give single solid phase microstructure, while partial solutions give two or more phases that may or may not be homogeneous in distribution, depending on thermal (heat treatment) history. Alloys usually have different properties from those of the component elements. In the practice of the present invention, an alloy can have gradient(s) in stoichiometry due to processing techniques.

A metal species is considered to be alloyable in a resultant alloy if the alloy includes at from 0.8 to 99.2 atomic percent, preferably from 1 to 99 atomic percent of that metal based on the total metal content of the alloy. Alloyable species are distinguished from dopants, which are incorporated into semiconductor films or the like at substantially lower concentrations, e.g., concentrations in the range of 1×10²⁰ cm⁻³ to 1×10¹⁵ cm⁻³ or even less.

Exemplary metal species that would be alloyable with pnictide film compositions include one or more of Mg, Ca, Be, Li, Cu, Na, K, Sr, Rb, Cs, Ba, Al, Ga, B, In, Sn, Cd, and combinations of these. Mg is more preferred. By way of example, Mg is alloyable with Zn₃P₂ to form a Mg₃ₓZn_{3*(1-x)}P₂ alloy in which x has a value such that the Mg content may be in the metal (or cation) atomic percent range of 0.8 to 99.2 percent based on the total amount of Mg and Zn. More preferably, x has a value in the range from 1 to 5 percent.

The pnictide compositions used in the practice of the present invention may be amorphous and/or crystalline as supplied or formed, but desirably are crystalline prior to carrying out the treatment according to the present invention. Crystalline embodiments may be single crystal or polycrystalline, although single crystal embodiments are preferred. Exemplary crystalline phases may be tetragonal, cubic, monoclinic, and the like. Tetragonal crystalline phases are more preferred, particularly for zinc phosphide.

Pnictide compositions having photovoltaic and/or semiconducting characteristics may be of n-type or p-type. Such materials may be intrinsically and/or extrinsically doped. In many embodiments, extrinsic dopants may be used in a manner effective to help establish a desired carrier density, such as a carrier density in the range from about 10¹³ cm⁻³to about 10²⁰ cm⁻³. A wide range of extrinsic dopants may be used. Examples of extrinsic dopants include Al, Ag, B, Mg, Cu, Au, Si, Sn, Ge, F, In, Cl, Br, S, Se, Te, N, I, H, combinations of these and the like.

Pnictide films in the practice of the present invention may have a wide range of thicknesses. Suitable thicknesses may depend on factors including the purpose of the film, the composition of the film, the methodology used to form the film, the crystallinity and morphology of the film, and/or the like. For photovoltaic applications, a film desirably has a thickness effective to capture incident light for photovoltaic performance. If the film were to be too thin, too much light may pass through the film without being absorbed. Layers that are too thick will provide photovoltaic functionality, but are wasteful in the sense of using more material than is needed for effective light capture and reduced fill factors due to increased series resistance. In many embodiments, pnictide films have a thickness in the range from about 10 nm to about 10 microns, or even from about 50 nm to about 1.5 microns. By way of example, a thin film having p-type characteristics that is used to form at least part of a p-n, p-i-n, Schottky junction, or the like, may have a thickness in the range from about 1 to about 10 μm, preferably about 2 to about 3 μm. A thin film having n-type characteristics that is used to form at least part of a p-n, p-i-n, or the like, may have a thickness in the range from about 10 nm to about 2 μm, preferably about 50 nm to about 0.2 μm.

Pnictide films may be formed from a single layer or multiple layers. Single layers may have a generally uniform composition throughout or may have a composition that shifts throughout the film. A layer in a multilayer stack typically has a different composition than adjacent layer(s), although the composition of nonadjacent layers may be the similar or different in such embodiments.

Pnictide films desirably are supported upon a suitable substrate. Exemplary substrates may be rigid or flexible, but desirably are flexible in those embodiments in which the resultant microelectronic device may be used in combination with non-flat surfaces. A substrate may have a single or multilayer construction. When the pnictide film is to be incorporated into an optoelectronic device, the substrate may include at least a portion of those layers that would be underneath the film in the finished device if the device is built right side up. Alternatively, the substrate may be at least a portion of the layers that would be above the film in the finished device if the device is being fabricated upside down.

Prior to forming the emitter layer on the pnictide absorber film, the pnictide absorber film can be subjected to one or more optional treatments in order to enhance the quality of the interface between the pnictide absorber film and the emitter film. Such optional pre-treatments may be carried for a variety of reasons, including to polish the surface, to smooth the surface, to clean the surface, to rinse the surface, to etch the surface, to reduce electronic defects, oxide removal, passivation, reduce surface recombination velocity, combinations of these, and the like. For example, in one exemplary methodology, polycrystalline boules of zinc phosphide semiconductor material are grown using procedures described in the technical literature. The boules are diced into rough wafers. As an exemplary pre-pretreatment methodology, the rough wafers are polished using a suitable polishing technique. The surface quality of the wafers is further improved by an additional pre-treatment in which the wafer surfaces are subjected to that involves at least two stages of etching and at least one oxidation that in combination not only clean the pnictide film surface, but also render the film surface highly smooth with reduced electronic defects. The surface is well-prepared for further fabrication steps. This integrated etching/oxidation/etching treatment is described Assignee's co-pending U.S. Provisional Patent Application filed on the same date as the present application in the names of Kimball et al., titled METHOD OF MAKING PHOTOVOLTAIC DEVICES INCORPORATING IMPROVED PNICTIDE SEMICONDUCTOR FILMS, and having Attorney Docket No. Docket No 71958 (DOW0058P1), the entirety of which is incorporated herein by reference for all purposes.

An another example of an optional pre-treatment, the properties of the pnictide film can be further enhanced using the metallization/annealing/alloying/removal techniques described in Assignee's co-pending U.S. Provisional Patent Application filed on the same date as the present application in the names of Kimball et al., titled METHOD OF MAKING PHOTOVOLTAIC DEVICES INCORPORATING IMPROVED PNICTIDE SEMICONDUCTOR FILMS USING METALLIZATION/ANNEALING/REMOVAL TECHNIQUES, and having Attorney Docket No. Docket No 71956 (DOW0056P1), the entirety of which is incorporated herein by reference for all purposes. This treatment removes impurities and results in a highly passivated surface with reduced electronic defects.

The emitter layer of the present invention is a semiconductor that incorporates ingredients including one or more Group II elements and one or more Group VI elements. Group II elements include at least one of Cd and/or Zn. Zn is preferred. The Group VI materials, also referred to as chalcogens, include O, S, Se, and/or Te. S and/or Se are preferred. S is more preferred in some embodiments. A combination of S and Se is more preferred in other representative embodiments, wherein the atomic ratio of S to Se is in the range from 1:100 to 100:1, preferably 1:10 to 10:1, more preferably 1:4 to 4:1. In one particularly preferred embodiment, using 30 to 40 atomic percent S based on the total amount of S and Se would be suitable. The emitter materials that incorporate one or more chalcogens also may be referred to as chalcogenides herein.

A particularly preferred Group II/Group VI semiconductor comprises zinc sulfide. Some embodiments of zinc sulfide may have a sphalerite or wurtzite crystalline structure. Intrinsically, the cubic form of zinc sulfide has a band gap of 3.68 eV at 25° C. whereas the hexagonal form has a band gap of 3.91 eV at 25° C. In other embodiments, zinc selenide may be used. Zinc selenide is an intrinsic semiconductor with a band gap of about 2.70 eV at 25° C.

Zinc sulfide selenide semiconductors also may be used. Illustrative embodiments of zinc sulfide selenide may have the composition ZnS_{y}Se_{1-y}, where y has a value such that the atomic ratio of S to Se is in the range from 1:100 to 100:1, preferably 1:10 to 10:1, more preferably 1:4 to 4:1. In one particularly preferred embodiment, using 30 to 40 atomic percent S based on the total amount of S and Se would be suitable.

Advantageously, ZnS, ZnSe, or zinc sulfide selenide materials offer the potential to optimize several device parameters, including conduction band offset, band gap, surface passivation, and the like. These materials also may be grown from compound sources as taught in co-pending U.S. Provisional Patent Application having Ser. No. 61/441,997, filed Feb. 11, 2011, in the names of Kimball et al. titled Methodology For Forming Pnictide Compositions Suitable For Use In Microelectronic Devices and having Docket No 70360 (DOW0039P1), which is advantageous for many reasons including facilitating manufacture on industrial scales. However, while these zinc chalcogenides are very good matches for pnictide semiconductors such as zinc phosphide, the magnitude of the conduction band offset between the two kinds of materials can still be unduly high. The lattice mismatch may be greater than desired. For instance, ZnS and Zn₃P₂ have a conduction band offset of 0.3 eV, which is still large enough to cause undue loss in V_{oc} in some modes of practice. There can also be a lattice mismatch (about 5.5%) between the two materials.

The present invention provides strategies to reduce the conduction band offset and improve the lattice match between the absorber and emitter. In the practice of the present invention, at least one tuning agent, preferably at least one metal tuning agent, is incorporated into the Group II/Group VI semiconductor as a way to reduce the conduction band offset between the emitter and the absorber. Reducing the conduction band offset between the emitter and absorber layers in this way has the potential to increase the efficiency and open circuit voltage of the resultant photovoltaic device.

Exemplary metal tuning agents are selected from one or more of Mg, Ca, Be, Li, Cu, Na, K, Sr, Sn, F, combinations of these, and the like. Mg, Ca, Be, Sn, F, and Sr are preferred. Mg is most preferred.

The metal tuning agent(s) are incorporated into the emitter layer in an amount effective to achieve the desired adjustment to the conduction band offset. For instance, consider a mode of practice in which Mg is being added to n-type ZnS that is alloyed or doped with aluminum in order to more closely match the ZnS with an underlying absorber formed from ingredients including p-type Zn₃P₂. If too little or too much of the tuning agent is added to the zinc sulfide, the conduction band offset between the absorber layer and the emitter layer may be greater than desired.

The amount of tuning agent(s) added to the emitter material can vary over a wide range. As general guidelines, the tuned emitter material may include from 1 metal atomic percent to 80 metal atomic percent, preferably 5 atomic percent to 70 atomic percent of the tuning agents. At these levels, the tuning agents are believed to be alloyed into the emitter layer, and the resultant emitter material is an alloy.

The tuning agent(s) may be incorporated into all or only selected portions of the emitter layer. In some modes of practice, a goal of tuning is to more closely match the electron affinity characteristics of the emitter layer to the electron affinity characteristics of the absorber layer. When this is a goal, an optional mode of practice involves incorporating the tuning agent only in a portion of the emitter layer that is proximal to the absorber layer. This mode of practice recognizes that the electron affinity matching can be achieved sufficiently in this way without having to incorporate the tuning agents throughout the emitter layer. Additionally, a thinner tuned region may be more desirable in those embodiments in which the resultant tuned alloy might be more resistive than the untuned material. In such modes of practice, the tuning agent(s) can be incorporated into the emitter layer proximal to the absorber layer to a desired depth. A suitable depth may be in the range from 1 nm to 200 nm, preferably 5 nm to 100 nm, more preferably 10 nm to 50 nm in many embodiments. After this, the incorporation of the tuning agent(s) into further growth of addition portions of the emitter layer can be stopped gradually or all at once.

In addition to the one or more tuning agents, the one or more Group II elements, and the one or more Group VI elements, one or more additional constituents also may be incorporated into the emitter layer. Examples of such constituents include dopants to enhance n-type characteristics and/or other alloyed elements to increase the bandgap of the n-type emitter layer; combinations of these and the like. Exemplary dopants that may be included in the emitter layer include Al, Cd, Sn, In, Ga, F, combinations of these, and the like. Aluminum doped embodiments of chalcogenide semiconductors are described in Olsen et al., Vacuum-evaporated conducting ZnS films, Appl. Phys. Lett. 34(8), 15 Apr. 1979, 528-529; Yasuda et. al., Low Resistivity Al-doped ZnS Grown by MOVPE, J. of Crystal Growth 77 (1986) 485-489. Tin doped embodiments of chalcogenide semiconductors are described in Li et al, Dual-donor codoping approach to realize low-resistance n-type ZnS semiconductor, Appl. Phys. Lett. 99(5), August 2011, 052109.

Emitter films in the practice of the present invention, including the tuned region(s) if only portion(s) are tuned, may have a wide range of thicknesses. Suitable thicknesses may depend on factors including the purpose of the film, the composition of the film, the methodology used to form the film, the crystallinity and morphology of the film, and/or the like. For photovoltaic applications, if the emitter film were to be too thin, then the device may be shorted or the depletion region at the interface could unduly encompass the emitter layer. Layers that are too thick might_result in excessive free-carrier recombination, hurting the device current and voltage and ultimately decreasing device performance. In many embodiments, emitter films have a thickness in the range from about 10 nm to about 1 microns, or even from about 50 nm to about 100 nm.

Tuning agents advantageously allow the conduction band offset between the emitter and absorber films to be reduced. However, tuning may cause an increase in lattice mismatch between the tuned emitter and the absorber. For instance, prior to tuning ZnS with respect to Zn₃P₂, the junction between these two materials is associated with a conducton band offset of about 0.3 eV and a lattice mismatch of about 5.5%. Tuning the ZnS with Mg can reduce the conduction band offset to less than 0.1 eV. Unfortunately, the lattice mismatch tends to increase to>5.5% as a result of tuning. In the practice of the present invention, the emitter film can be formed with a combination of chalcogens in order to reduce the lattice mismatch between the tuned material and the pnictide semiconductor while preserving the benefits that tuning provided with respect to the conduction band offset.

To facilitate improving the lattice match, preferred chalcogenide films incorporate at least two chalcogens. For example, the chalcogenide films may incorporate S and at least one of Se and/or Te. More preferred films incorporate S and Se. The present invention appreciates that the lattice match between the emitter films and the pnictide films is a function of the relative amount of chalcogens incorporated into the chalcogenide layer. Therefore, the ratio between the two chalcogens in the chalcogenide composition can be varied in order to adjust the lattice match characteristics.

A particularly preferred tuned composition is a quaternary alloy incorporating Zn, Mg, S, and Se. Relative to a chalcogenide of just ZnS, the Mg helps to reduce the conduction band offset between the tuned composition and the pnictide semiconductor film. Further, to the extent that tuning ZnS with Mg would increase the lattice mismatch with the pnictide film, the Se content helps to counteract that and improve the lattice matching.

A particularly preferred quaternary alloy has the formula ZnₓMg₁₋ₓS_{y}Se_{1-y}, wherein x has a value such that Mg is 0.1 to 99.2, preferably 0.1 to 5.0 atomic percent of the metal content of the alloy based on the total amount of Zn and Mg, and y has a value such that the atomic ratio of S to Se is in the range from 1:100 to 100:1, preferably 1:10 to 10:1, more preferably 1:4 to 4:1.

The tuned emitter layer can be made using any suitable depositions techniques. According to preferred techniques, the emitter layers is prepared from suitable source compounds in which a vapor flux one or more suitable Group II/GroupVI source compound(s), the tuning agent(s), optional dopant(s), and other optional consituents, are generated in a first processing zone. The vapor flux optionally is treated in a second processing zone distinct from the first processing zone to enhance deposition performance. The treated vapor flux is used to grow the emitter film on a suitable substrate comprising the pinctide-containing absorber film, thereby forming the desired photovoltaic junction or precursor thereof. These techniques and a corresponding apparatus that practices these techniques are described in more detail in co-pending U.S. Provisional Patent Application titled METHODOLOGY FOR FORMING PNICTIDE COMPOSITIONS SUITABLE FOR USE IN MICROELECTRONIC DEVICES, Ser. No. 61/441,997, filed Feb. 11, 2011, in the names of Kimball et al., and having Attorney Docket No 70360 (DOW0039P1), the entirety of which is incorporated herein by reference for all purposes.

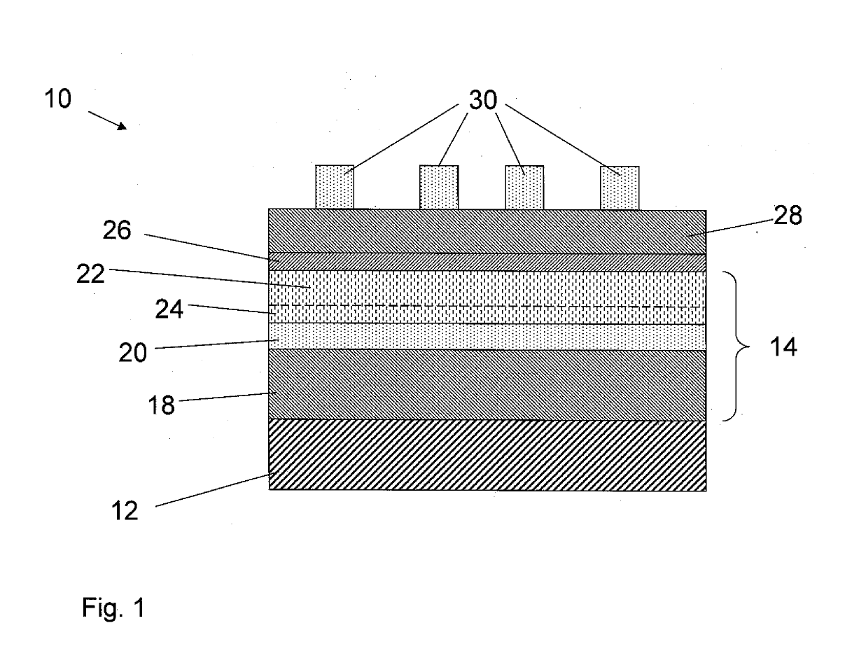

FIG. 1 schematically illustrates a photovoltaic device 10 incorporating films of the present invention. Device 10 includes substrate 12 supporting p-n photovoltaic junction 14. Substrate 12 for purposes of illustration is p+ GaAs (p<0.001 ohm-cm) with an InGa back contact (not shown). Junction 14 includes p-type pnictide semiconductor film 18 as an absorber. For purposes of illustration, the pnictide absorber may be zinc phosphide, optionally doped with Ag. An alloy layer 20 of Mg and zinc phosphide obtained using metallization/annealing/removal techniques is formed in the region between the film 18 and the emitter film 22.

Emitter film 22 is formed according to principles of the present invention. For purposes of illustration, emitter film 22 is ZnS highly doped with Al and includes region 24 proximal to absorber film 18 and alloy layer 20. Region 24 is alloyed with Mg. Alloying region 24 with Mg adjusts the electron affinity characteristics of film 22 to more closely match the electron affinity characteristics of film 24. In this embodiment, only region 24 of film 22 incorporates the tuning agent Mg. In other embodiments, the tuning agent may be incorporated throughout the entire film 22. The concentration of the tuning agent throughout the film 22 need not be uniform. For instance, the concentration can tend to decrease with increasing distance from the absorber film 18.

Window layer 26 is formed on emitter film 24. Such layers provide many benefits, including enhancing band gap properties, preventing shunt propagation, and the like. Transparent conducting electrode layer 28 is formed on the window layer 26. In illustrative embodiments, the transparent conducting electrode material is aluminum doped zinc oxide or indium tin oxide or tin oxide or in some embodiments the window layer may comprise a bilayer comprising an instrinsic or resistive oxide layer and a conductive transparent oxide layer. Collection grid 30 is formed over layer 28. Collection grid 30 may be formed in some embodiments from materials such as Ag, Ni, _Al, Cu, In, Au, and combinations of these. The grid materials may be in admixture such as in an alloy or intermetallic composition and/or may be in multiple layers. One or more environmental protection barriers (not shown) can be used to protect device 10 from the ambient.

The present invention will now be further described with reference to the following illustrative examples.

### EXAMPLE 1

### Substrate Preparation

A solid state ZnS/Zn₃P₂ heterjunction solar cell is fabricated on a degeneratively doped, p-type, GaAs (001) single crystal substrate using compound source, molecular beam epitaxy (MBE) techniques according to techniques and a corresponding apparatus that practices these techniques are described in more detail in co-pending U.S. Provisional Patent Application titled METHODOLOGY FOR FORMING PNICTIDE COMPOSITIONS SUITABLE FOR USE IN MICROELECTRONIC DEVICES, Ser. No. 61/441,997, filed Feb. 11, 2011, in the names of Kimball et al., and having Attorney Docket No 70360 (DOW0039P1). The growth is performed in ultra high vacuum (UHV) molecular beam epitaxy chamber with a base pressure of 10⁻¹⁰ torr. The chamber is equipped with compound sources of Zn₃P₂ and ZnS, as well as elemental sources of Al, Ag, Zn, and Mg.

The backside of the GaAs substrate is coated with a Pt—Ti—Pt low resistivity back contact prior to cell fabrication. The substrate is mounted to a molybdenum sample chuck using Cu—Be clips and loaded into a vacuum chamber. The back of the substrate is painted with and In—Ga liquid eutectic to promote thermal contact to the chuck.

The GaAs native oxide is removed before each thin film growth. Two removal procedures are used. A first procedure uses a UHV anneal above 580° C. to thermally desorb surface oxides. The second procedure involves directly reducing the native oxide by exposing the surface to an atomic hydrogen beam at a temperature between 400° C. to 500° C. Hydrogen radicals are created using a low pressure radio frequency (RF) plasma source with a deflection plate to remove ionized species. The hydrogen treatment is preferred since it leaves an atomically smooth growth surface absent of pits due to overheating of the substrate. After removal of the oxide, the substrate is cooled to the zinc phosphide growth temperature.

### EXAMPLE 2

### Zinc Phosphide Growth

Zinc phosphide film growth is performed by subliming 99.9999% Zn₃P₂ from a Knudsen effusion cell. The effusion cell is heated to above 350° C., providing a beam pressure between 5×10⁻⁷ and 2×10⁻⁶ Torr as determined by a translatable nude ionization gauge. The growth is performed at a substrate temperature of 200° C. The film deposition rate is about 0.3 to 1.0 angstroms/s. A typical film thickness is 400 to 500 nm. Thicker films are possible but require longer growth rates or higher beam pressures. Elemental Ag is incorporated as a dopant during the growth process by co sublimation from an additional Ag source. The Ag source is operated between 700° C. and 900° C. Immediately after Zn₃P₂ growth, the substrate temperature is decreased to the ZnS deposition temperature.

### EXAMPLE 3

### Tuned ZnS Growth

ZnS growth is performed using a Knudsen effusion cell containing 99.9999% ZnS. The effusion cell is heated to 850° C. for deposition. This creates a beam pressure of about 1.5×10-6 Torr. During ZnS growth, the substrate is held at 100° C. Under this beam pressure and substrate temperature, ZnS growth rate is about 1 angstrom/s. A film having a thickness of 100 nm is grown. During growth, Al and Mg are co-introduced with the ZnS. Al is provided using an electron beam evaporator filled with 99.9999% Al metal. The extent of Al incorporation and therefore dopant density is controlled by the power supplied to the evaporator. The Al density in the grown film is typically between 1×10¹⁸ and 1×10¹⁹ cm⁻³. Mg is provided using an effusion cell filled with 99.9999% Mg with operating temperature between 300° C. and 600° C. Mg is co-introduced only during the first 10 to 100 nm of film growth. In alternative embodiments, Mg could be included throughout the ZnS film.

### EXAMPLE 4

### Forming a Cell

The Zn₃P₂ and ZnS films form a p-n heterojunction. After these films are grown, the workpiece is removed from the apparatus and transferred to another apparatus in which 70 nm of indium tin oxide as a transparent conducting oxide is sputter deposited onto the ZnS through a 1×1 mm shadow mask. The photovoltaic performance of the device may be evaluated under suitable illumination, e.g., AM1.5 1-sun illumination.

Other embodiments of this invention will be apparent to those skilled in the art upon consideration of this specification or from practice of the invention disclosed herein. Various omissions, modifications, and changes to the principles and embodiments described herein may be made by one skilled in the art without departing from the true scope and spirit of the invention which is indicated by the following claims.

1. A method of making a solid state photovoltaic heterojunction or precursor thereof, comprising the steps of:
a. providing a pnictide semiconductor film; and
b. forming a chalcogenide semiconductor film directly or indirectly on the pnictide semiconductor film, said semiconductor chalcogenide film comprising at least one Group II element and at least one Group VI element, and wherein at least a portion of the chalcogenide semiconductor film proximal to the pnictide semiconductor film incorporates at least one tuning agent that reduces the conduction band offset between the pnictide semiconductor film and the chalcogenide semiconductor film relative to an otherwise identical chalcogenide semiconductor film composition formed under the same conditions with none or lesser amount(s) of at least one tuning agent.

2. The method of claim 1, wherein the pnictide semiconductor film comprises zinc and phosphorous.

3. The method of claim 1, wherein the pnictide semiconductor film comprises an alloy composition.

4. The method of claim 3, wherein the alloy composition is proximal to an interface between the pnictide semiconductor film and the chalcogenide semiconductor film.

5. The method of claim 1, wherein the pnictide semiconductor film comprises at least one of Al, Ga, In, Tl, Sn, and Pb.

6. The method of claim 1, wherein the pnictide semiconductor film comprises at least one of B, F, S, Se, Te, C, O, and H.

7. The method of claim 1, wherein the chalcogenide semiconductor film comprises S and/or Se.

8. The method of claim 1, wherein the chalcogenide semiconductor film comprises Zn, S, and Mg.

9. The method of claim 1, wherein the chalcogenide semiconductor film comprises Zn, S, Se and Mg.

10. The method of claim 1, wherein the at least one tuning agent is used in an amount such that the conduction band offset between the pnictide semiconductor film and the chalcogenide semiconductor film is less than 0.1 eV.

11. The method of claim 1, wherein the at least one tuning agent is used in an amount effective to achieve a desired, pre-determined conduction band offset between the pnictide semiconductor film and the chalcogenide semiconductor film.

12. The method of claim 1, wherein the at least one tuning agent is selected from one or more of Mg, Ca, Be, Li, Cu, Na, K, Sr, Sn, and/or F.

13. The method of claim 1, wherein the at least one tuning agent is selected from one or more of Mg, Ca, Be, Sr, Sn, and/or F.

14. The method of claim 1, wherein the at least one tuning agent comprises Mg.

15. The method of claim 1, wherein the chalcogenide semiconductor film comprises a portion include from 1 to 80 atomic percent of the at least one tuning agent.

16. The method of claim 15, wherein the at least one tuning agent is incorporated into a portion of the chalcogenide semiconductor film that is proximal to the pnictide semiconductor film.

17. The method of claim 15, wherein the at least one tuning agent is incorporated throughout the chalcogenide semiconductor film at an average content of from 1 to 80 atomic percent.

18. The method of claim 1, wherein Step (b) comprises the steps of:
i. heating a compound comprising at least one Group II element and at least one Group VI element to generate a vapor species;
ii. depositing the vapor species or a derivative thereof directly or indirectly onto the p-type pnictide semiconductor film; and
iii. co-depositing at least one of Mg and Ca during at least a portion of the time that the n-type semiconductor film is deposited under conditions such that at least a portion of the formed n-type semiconductor film proximal to the p-type pnictide semiconductor film incorporates at least one of Mg and/or Ca.

19. A photovoltaic device, comprising:
(a) a p-type region comprising at least one p-type, pnictide semiconductor composition; and
(b) an n-type region provided directly or indirectly on the absorber region, said n-type region comprising at least one Group II element and at least one Group VI element, and wherein at least a portion of the n-type region proximal to the p-type absorber region incorporates at least one of Mg and/or Ca.
